(19) United States
(12) Patent Application Publication
(10) Pub. No.: US 2023/0060636 A1
(43) Pub. Date: Mar. 2, 2023

(54) LIGHT EMITTING DEVICE

(71) Applicant: TOYODA GOSEI CO., LTD., Kiyosu-shi (JP)

(72) Inventor: Koichi MIZUTANI, Kiyosu-shi (JP)

(21) Appl. No.: 17/897,578

(22) Filed: Aug. 29, 2022

(30) Foreign Application Priority Data
Aug. 30, 2021 (JP) 2021-140365

(51) Int. Cl. H01L 33/32; H01L 33/38

(52) U.S. Cl. CPC H01L 33/32; H01L 33/382

(57) ABSTRACT

In an ultraviolet light emitting device made of a group III nitride semiconductor, a contact layer is provided on a reflective insulating film along a bottom surface, a side surface, and an upper surface of a hole. The contact layer and an n layer are in contact with each other via a plurality of holes. The contact layer is made of Si-doped n-GaN. A lower surface of the contact layer is in contact with the n layer, and an upper surface thereof is in contact with an n electrode. The contact layer is not in contact with the n layer except for regions of the holes. The n electrode is provided on almost the entire upper surface of the contact layer. Therefore, a contact area between the n electrode and the contact layer is wider than a contact area between the contact layer and the n layer.

### CROSS-REFERENCE TO RELATED APPLICATIONS

The present application claims the benefit of priority of Japanese Patent Application No. 2021-140365, filed on Aug. 30, 2021, the content of which is incorporated herein by reference.

### TECHNICAL FIELD

The present invention relates to an ultraviolet light emitting device made of a group III nitride semiconductor.

### BACKGROUND ART

In recent years, attention has been paid to the use of ultraviolet LEDs for sterilization and disinfection, and research and development for improving the efficiency of ultraviolet LEDs are being actively carried out.

In ultraviolet LEDs in the related art, AlN, n-AlGaN, a light emitting layer, p-AlGaN, and p-GaN are laminated on a sapphire substrate in this order, a part of a region from a surface side of p-GaN is etched to expose n-AlGaN, and an n electrode is formed on the exposed n-AlGaN.

JP-A-2010-161311 discloses that when an intermediate layer made of n-Al_{y}Ga_{1-y}N (0≤y≤0.5) is provided between n-AlₓGa₁₋ₓN (0.7≤x≤1.0) and an n electrode, contact resistance between n-AlₓGa₁₋ₓN and the n electrode is reduced. A similar technique is disclosed in JP-A-2012-89754.

### SUMMARY OF INVENTION

However, when an Al composition ratio in n-AlGaN is high, even with the method disclosed in JP-A-2010-161311 and JP-A-2012-89754, the contact resistance between n-AlGaN and the n electrode cannot be sufficiently reduced, and it is necessary to increase an area of the n electrode. Therefore, it is necessary to widen an etching area for exposing the n layer, and a light emitting area becomes narrow, so that a highly efficient device cannot be obtained.

In cope with this, an object of the present disclosure to provide an ultraviolet light emitting device made of a group III nitride semiconductor and capable of reducing the resistance between the n layer and the n electrode.

An ultraviolet light emitting device made of a group III nitride semiconductor according to the present disclosure includes: a substrate; an n layer located on the substrate; a light emitting layer located on the n layer; a p layer located on the light emitting layer; a hole reaching the n layer from a surface of the p layer; and an n electrode connected to the n layer exposed on a bottom surface of the hole, in which the n layer is made of n-AlGaN having an Al composition ratio of 70% or more, a contact layer made of n-AlGaN having an Al composition ratio smaller than that of the n layer is further provided between the n layer and the n electrode, the contact layer is in contact with both the n layer and the n electrode, and a contact area between the n electrode and the contact layer is wider than a contact area between the contact layer and the n layer.

In the above light emitting device, when the contact area between the n electrode and the contact layer is S1, and the contact area between the contact layer and the n layer is S2, S1/S2 may be 1.02 to 5.

In the above light emitting device, an upper surface of a region on an upper surface of the contact layer corresponding to an upper part of the hole may be located above a lower surface of the p layer.

In the above light emitting device, the contact layer may be formed from the upper part of the p layer or a side surface of the hole to the bottom surface of the hole.

In the above light emitting device, the contact layer may be made of n-GaN.

According to the ultraviolet light emitting device made of a group III nitride semiconductor, resistance between the n layer made of n-AlGaN and the n electrode can be sufficiently reduced.

### BRIEF DESCRIPTION OF DRAWINGS

FIG. 1 is a diagram showing a configuration of a light emitting device according to a first embodiment.

FIG. 2A is a diagram showing a step of producing the light emitting device according to the first embodiment.

FIG. 2B is a diagram showing a step of producing the light emitting device according to the first embodiment.

FIG. 2C is a diagram showing a step of producing the light emitting device according to the first embodiment.

FIG. 3A is a diagram showing a step of producing the light emitting device according to the first embodiment.

FIG. 3B is a diagram showing a step of producing the light emitting device according to the first embodiment.

FIG. 3C is a diagram showing a step of producing the light emitting device according to the first embodiment.

FIG. 4A is a diagram showing a step of producing the light emitting device according to the first embodiment.

FIG. 4B is a diagram showing a step of producing the light emitting device according to the first embodiment.

### DESCRIPTION OF EMBODIMENTS

Hereinafter, a specific embodiment of the present invention will be described with reference to the drawings, but the present invention is not limited to the embodiment.

### First Embodiment

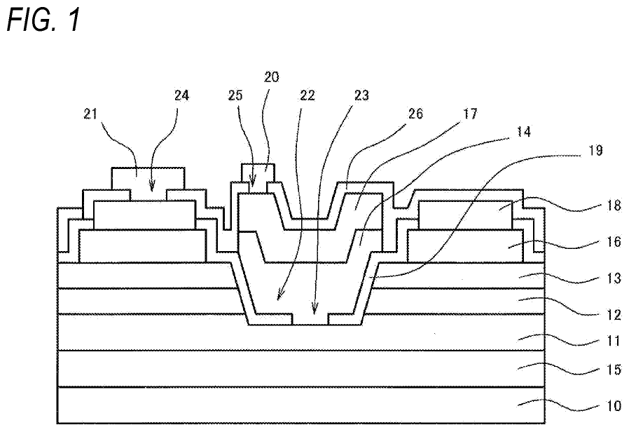

FIG. 1 is a diagram showing a configuration of an ultraviolet light emitting device according to a first embodiment. An emission wavelength is, for example, 200 nm to 280 nm. As shown in FIG. 1, a light emitting device according to the first embodiment includes a substrate 10, a buffer layer 15, an n layer 11, a light emitting layer 12, a p layer 13, a contact layer 14, a transparent electrode 16, an n electrode 17, a p electrode 18, a reflective insulating film 19, an n-side junction electrode 20, and a p-side junction electrode 21.

### (Configuration of Substrate 10)

The substrate 10 is a substrate made of sapphire whose main plane is the c-plane. In addition to sapphire, any material may be used as long as it has a high transmittance with respect to the emission wavelength and can grow a group III nitride semiconductor. In the light emitting device according to the first embodiment, light is extracted from a back surface side of the substrate 10.

### (Configuration of Buffer Layer 15)

The buffer layer 15 is located on the substrate 10. The buffer layer 15 is made of AlN. By providing the buffer layer 15, flatness and crystallinity of a semiconductor layer are improved.

### (Configuration of n Layer 11)

Then layer 11 is located on the buffer layer 15. The n layer 11 is made of n-AlGaN having an Al composition ratio of 70% or more. The n-type impurity is Si. Here, the Al composition ratio in the group III nitride semiconductor is a molar ratio (%) of Al to a group III metal. That is, when the group III nitride semiconductor is represented by a general formula AlₓGa_{y}In_{z}N (0≤x≤1, 0≤y≤1, 0≤z≤1, x+y+z=1), the Al composition ratio is x×100(%). The n layer 11 may be composed of a plurality of layers. In this case, it is sufficient that the Al composition ratio in the uppermost layer of the n layer 11 is 70% or more. The Al composition ratio in the n layer 11 is more preferably 75% to 90%, and still more preferably 80% to 85%.

### (Configuration of Light Emitting Layer 12)

The light emitting layer 12 is located on the n layer 11. The light emitting layer 12 has an MQW structure in which a well layer and a barrier layer are alternately and repeatedly laminated. The number of repetitions is, for example, 2 to 5. The well layer is made of AlGaN, and the Al composition ratio thereof is set according to a desired emission wavelength. The barrier layer is made of AlGaN having an Al composition ratio larger than that of the well layer. AlGaInN, which has a bandgap energy larger than that of the well layer, may be used. The light emitting layer 12 may have an SQW structure.

### (Configuration of p Layer 13)

The p layer 13 is located on the light emitting layer 12. The p layer 13 has a structure in which p-AlGaN and p-GaN are laminated in order from a light emitting layer 12 side. The p-type impurity is Mg. By using p-GaN as the uppermost layer in contact with the transparent electrode 16, contact between the transparent electrode 16 and the p layer 13 is reduced.

A plurality of holes 22 each having a depth reaching the n layer 11 are formed in a part of region on a surface of the p layer 13. The n layer 11 is exposed on a bottom surface of the hole 22. The holes 22 are arranged periodically, for example, in a honeycomb shape or a regular triangular lattice shape. The shape of the hole 22 in a plan view is a circle, a regular hexagon, or the like. The hole 22 may be one or may have a mesa shape. A side surface of the hole 22 may be vertical or inclined.

### (Configuration of Transparent Electrode 16)

The transparent electrode 16 is located on the p layer 13. The transparent electrode 16 is made of ITO. In addition to ITO, a transparent conductive material such as IZO can be used. The transparent electrode 16 does not have to be a transparent electrode, and an electrode material such as Ni/Au may be used. Here, “/” means laminated, and A/B means that the structure is laminated in the order of A and B. The same applies to the description of the material below.

### (Configuration of p Electrode 18)

The p electrode 18 is located on the transparent electrode 16. The p electrode 18 is made of, for example, Ni/Au or Ni/Al.

### (Configuration of Reflective Insulating Film 19)

The reflective insulating film 19 is continuously provided in a film shape on the p electrode 18, the transparent electrode 16, and the p layer 13, and over the side surface and the bottom surfaces of the hole 22. The reflective insulating film 19 protects the surface of the device and reflects light radiated from the light emitting layer 12 to improve light extraction. The reflective insulating film 19 is made of SiO₂. In addition to SiO₂, SiN, SiO₂/Al/SiO₂ and the like can be used, and DBR may be used. The DBR has a structure in which a high refractive index layer and a low refractive index layer are alternately laminated with a predetermined thickness, and has a structure in which a reflectance at a desired wavelength is increased by appropriately setting the thickness. For example, the high refractive index layer is made of HfO₂ and the low refractive index layer is made of SiO₂. When ultraviolet rays radiated from the light emitting layer 12 are reflected toward a substrate 10 side by the reflective insulating film 19, the light extraction is improved.

A plurality of holes 23 are provided in a region of the reflective insulating film 19 corresponding to upper parts of bottom surfaces of the holes 22. The holes 23 penetrates the reflective insulating film 19. In addition, the holes 23 are arranged periodically, for example, in a honeycomb shape or a regular triangular lattice shape. The shape of the hole 23 in a plan view is a circle, a regular hexagon, or the like. A side surface of the hole 23 may be vertical or inclined.

### (Configuration of Contact Layer 14)

The contact layer 14 is provided on the reflective insulating film 19 along the bottom surface, the side surfaces, and an upper surface (a region above the p layer 13 and near the side surfaces) of the hole 22. Although the contact layer 14 may not be provided on the side surfaces or the upper surface, it is preferable to provide the contact layer 14 on the side surfaces or the upper surface in order to increase a contact area between the n electrode 17 and the contact layer 14. In addition, the contact layer 14 is provided along bottom surfaced or side surfaces of the holes 23 or is provided to fill the holes 23, and the contact layer 14 and the n layer 11 are in contact with each other via the plurality of holes 23.

The contact layer 14 is made of Si-doped n-GaN. The contact layer 14 is not limited to being made of n-GaN, and may be made of n-AlGaN having an Al composition ratio smaller than that of the n layer 11. However, in order to sufficiently reduce resistance between the n electrode 17 and the n layer 11 as much as possible, it is preferable to reduce the Al composition ratio, the Al composition ratio is more preferably 10% or less, and the Al composition ratio is still more preferably 0%, that is, n-GaN. The contact layer 14 may be composed of a plurality of layers having different Al composition ratios.

A concentration of the n-type impurity in the contact layer 14 is, for example, 1×10¹⁸/cm³ to 1×10²¹/cm³. Within this range, the resistance between the n electrode 17 and the n layer 11 can be sufficiently reduced.

A thickness of the contact layer 14 is, for example, 1 nm to 10 μm. The thickness of the contact layer 14 does not have to be uniform, and it is sufficient that an average film thickness thereof is within this range. Within this range, the resistance between the n electrode 17 and the n layer 11 can be sufficiently reduced. The thickness is more preferable 10 nm to 1 μm, and still more preferably 20 nm to 500 nm.

A lower surface of the contact layer 14 is in contact with then layer 11, and an upper surface thereof is in contact with the n electrode 17. The contact layer 14 is provided on the reflective insulating film 19 and the contact layer 14 is not in contact with the n layer 11 except for regions of the holes 23. On the other hand, the n electrode 17 is provided on almost the entire upper surface of the contact layer 14. Therefore, a contact area between the n electrode 17 and the contact layer 14 is wider than a contact area between the contact layer 14 and then layer 11.

It is preferable that an upper surface of a region on the upper surface of the contact layer 14 corresponding to an upper part of the hole 23 is located above a lower surface of the p layer 13. It is easy to make heights of the n-side junction electrode 20 and the p-side junction electrode 21 uniform, and it is possible to increase junction strength with a submount when the light emitting device according to the first embodiment is mounted on the submount.

In the first embodiment, since the contact layer 14 is provided as described above, the resistance between the n electrode 17 and the n layer 11 can be reduced. The resistance between the n electrode 17 and the n layer 11 is a sum of contact resistance between the n electrode 17 and the contact layer 14, resistance of the contact layer 14, and contact resistance between contact layer 14 and n layer 11. Here, the contact resistance between the n electrode 17 and the contact layer 14 can be sufficiently reduced by using n-Gan as the material of the contact layer 14 and increasing the contact area between the n electrode 17 and the contact layer 14. In addition, the resistance of the contact layer 14 can be reduced because n-Gan is used as the material. Further, the contact resistance between the contact layer 14 and the n layer 11 can be reduced because both are made of group III nitride semiconductor materials. Therefore, in the light emitting device according to the first embodiment, the resistance between the n electrode 17 and the n layer 11 can be reduced as compared with a case where the n electrode 17 and the n layer 11 are in direct contact with each other. As a result, a forward voltage Vf of the light emitting device can be reduced, and reliability of the device can be improved.

In addition, since the contact resistance between the contact layer 14 and the n layer 11 is small, the contact area between the contact layer 14 and the n layer 11 can be reduced. Therefore, an area of the hole 22 for exposing the n layer 11 can be reduced, and a decrease in area of the light emitting layer 12 due to the formation of the hole 22 can be reduced. Therefore, a light emitting area can be made larger, and output can be improved as compared with a case of a light emitting device in the related art.

When the contact area between then electrode 17 and the contact layer 14 is S1, and the contact area between the contact layer 14 and the n layer 11 is S2, it is preferable that S1/S2 is 1.02 to 5. This is to further reduce the resistance between the n electrode 17 and the n layer 11 and further improve the output. It is more preferable that S1/S2 is 1.05 to 3.

### (Configuration of n Electrode 17)

The n electrode 17 is located on the contact layer 14. The n electrode 17 is made of, for example, Ti/Al, V, V/Au, V/Al, V/Ti/Al, V/Ti/Au, and Ni/Al. The n electrode 17 is covered with an insulating film 26. Holes 24 and 25 are each provided in a predetermined region of the insulating film 26. The holes 24 and 25 separately penetrate the insulating film 26, and the p electrode 18 and the n electrode 17 are separately exposed on a bottom surface of the insulating film 26.

### (Configuration of Junction Electrode)

The n-side junction electrode 20 is provided on the insulating film 26 and is in contact with the n electrode 17 via the hole 25. The p-side junction electrode 21 is provided on the insulating film 26 and is in contact with the p electrode 18 via the hole 24. The n-side junction electrode 20 and the p-side junction electrode 21 are made of, for example, Au.

In the light emitting device according to the first embodiment as described above, the contact layer 14 is provided between the n electrode 17 and the n layer 11, and the contact area between the contact layer 14 and the n electrode 17 is made larger than the contact area between the contact layer 14 and the n layer 11. Therefore, the resistance between the n electrode 17 and the n layer 11 can be reduced. In addition, the decrease in area of the light emitting layer 12 can be reduced, and the output can be improved.

Next, a method for producing the light emitting device according to the first embodiment will be described with reference to the drawings.

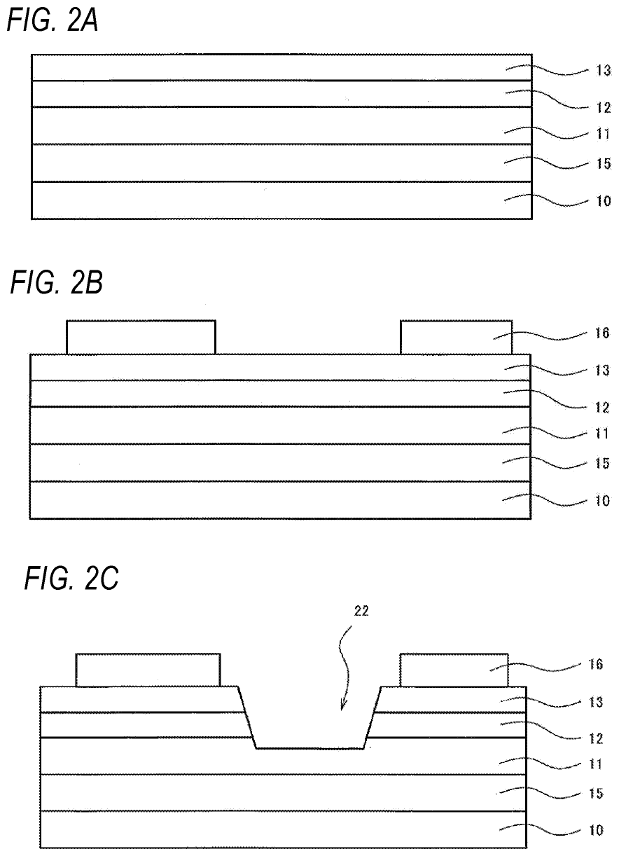

First, the buffer layer 15 made of AlN, the n layer 11 made of n-AlGaN, the light emitting layer 12, and the p layer 13 made of p-AlGaN/p-GaN are sequentially laminated on the substrate 10 made of sapphire by a MOCVD method (see FIG. 2A).

Next, the transparent electrode 16 made of ITO is formed in a predetermined region on the p layer 13 by sputtering (see FIG. 2B).

Next, a predetermined region of the p layer 13 is dry-etched until the n layer 11 is exposed to form the hole 22 (see FIG. 2C).

Next, a heat treatment is performed to crystallize the transparent electrode 16 to reduce the resistance, and to activate Mg in the p layer 13.

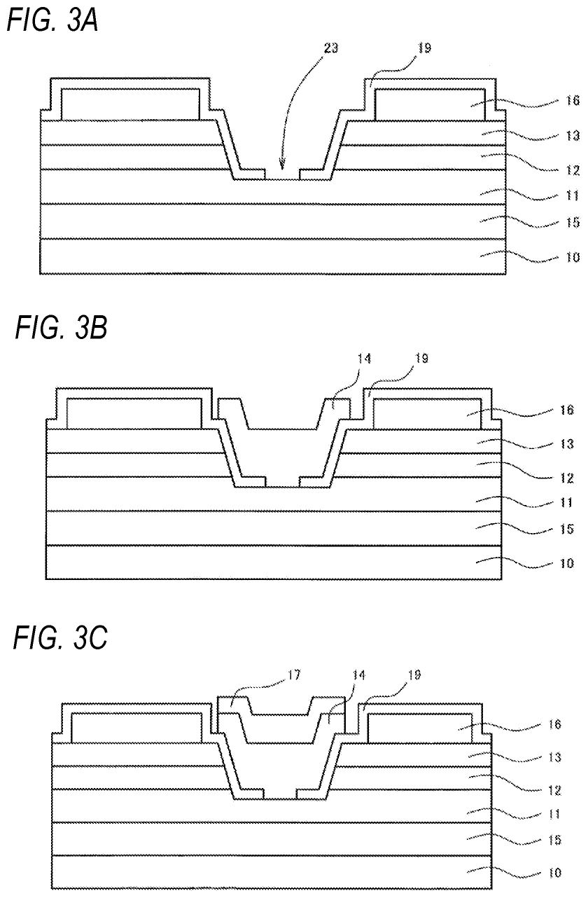

Next, the reflective insulating film 19 is formed on the entire upper surface of the device by a CVD method. Then, a predetermined region of the reflective insulating film 19 is etched to form the hole 23 (see FIG. 3A).

Next, the contact layer 14 made of n-GaN is formed in a predetermined region on the reflective insulating film 19, and the contact layer 14 and the n layer 11 are brought into contact with each other via the hole 23 (see FIG. 3B). Sputtering, MBE, PSD, MOCVD and the like are used for film formation. The film is preferably formed by sputtering from the viewpoint of preventing the p layer 13 from being inactivated by H₂. In addition, dry etching is used for patterning.

Next, the n electrode 17 is formed on the contact layer 14 by a method such as thin film deposition or sputtering (see FIG. 3C).

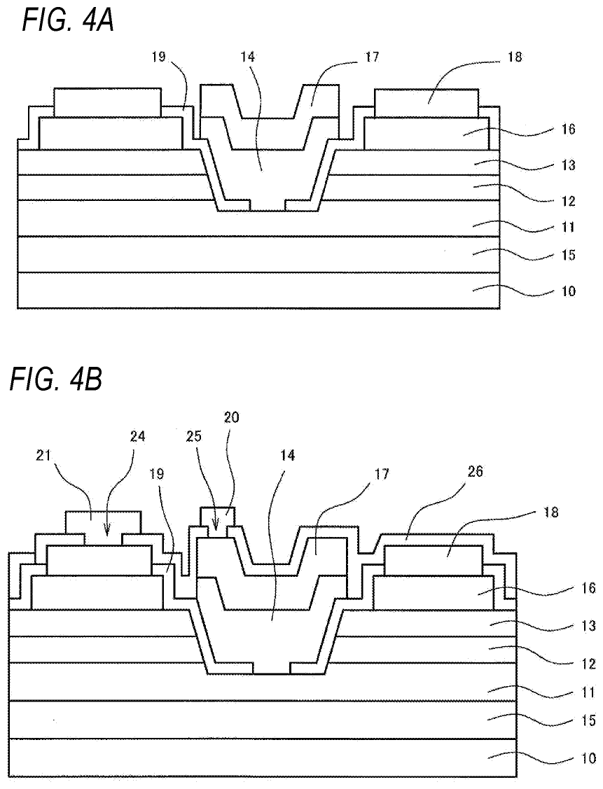

Next, a predetermined region of the reflective insulating film 19 is etched and open, and the p electrode 18 is formed on the transparent electrode 16 exposed in the opening by a method such as thin-film deposition or sputtering (see FIG. 4A).

Next, a heat treatment is performed to improve the contact between the p electrode 18 and the transparent electrode 16 and the contact between the n electrode 17 and the contact layer 14.

Next, the insulating film 26 is formed to cover the entire upper surface of the device. Then, a predetermined region of the insulating film 26 is etched to form the holes 24 and 25. Next, the p-side junction electrode 21 and the n-side junction electrode 20 are separately formed in a predetermined region on the insulating film 26 (see FIG. 4B).

Next, a back surface of the substrate 10 is polished to be thin, and the substrate 10 is divided into individual devices by laser and braking. As described above, the light emitting device according to first embodiment is produced.

### (Modification of Production Method)

The light emitting device according to the first embodiment may be produced as follows.

First, in the same manner as in the first embodiment, the buffer layer 15, the n layer 11, the light emitting layer 12, and the p layer 13 are laminated in this order on the substrate 10.

Next, a predetermined region of the p layer 13 is dry-etched until the n layer 11 is exposed to form the hole 22.

Next, the reflective insulating film 19 is formed on the entire upper surface of the device by a CVD method. Then, a predetermined region of the reflective insulating film 19 is etched to form the hole 23.

Next, the contact layer 14 is formed in a predetermined region on the reflective insulating film 19 in the same manner as in the first embodiment.

Next, the n electrode 17 is formed on the contact layer 14.

Next, a region in the reflective insulating film 19 above the p layer 13 is etched and open. Then, the transparent electrode 16 is formed on the p layer 13 exposed to the opening.

Next, the p electrode 18 is formed on the transparent electrode 16.

Next, a heat treatment is performed. In the first embodiment, the heat treatment is required to be performed twice to reduce the resistance of the transparent electrode 16 and improve the contact of the electrodes, but in the modification, the heat treatment can be performed only once.

Next, in the same manner as in the first embodiment, the insulating film 26, and the holes 24 and 25 are formed, the p-side junction electrode 21 and the n-side junction electrode 20 are formed, and the devices are divided.

The light emitting device according to the present disclosure can be used for sterilization, disinfection and the like.

What is claimed is:

1. An ultraviolet light emitting device made of a group III nitride semiconductor, the light emitting device comprising:
a substrate;
an n layer located on the substrate;
a light emitting layer located on the n layer;
a p layer located on the light emitting layer;
a hole reaching the n layer from a surface of the p layer; and
an n electrode connected to the n layer exposed on a bottom surface of the hole, wherein
the n layer is made of n-AlGaN having an Al composition ratio of 70% or more, a contact layer made of n-AlGaN having an Al composition ratio smaller than that of the n layer is further provided between the n layer and the n electrode, and the contact layer is in contact with both the n layer and the n electrode, and
a contact area between the n electrode and the contact layer is wider than a contact area between the contact layer and the n layer.

2. The light emitting device according to claim 1, wherein when the contact area between the n electrode and the contact layer is S1, and the contact area between the contact layer and then layer is S2, S1/S2 is 1.02 to 5.

3. The light emitting device according to claim 1, wherein an upper surface of a region on an upper surface of the contact layer corresponding to an upper part of the hole is located above a lower surface of the p layer.

4. The light emitting device according to claim 1, wherein the contact layer is formed from an upper part of the p layer or a side surface of the hole to the bottom surface of the hole.

5. The light emitting device according to claim 1, wherein the contact layer is made of n-GaN.
